(19) United States
(12) Patent Application Publication
(10) Pub. No.: US 2025/0275219 A1
(43) Pub. Date: Aug. 28, 2025

(54) SEMICONDUCTOR DEVICE AND METHOD FOR MANUFACTURING ELECTRODE-SEMICONDUCTOR MATERIAL JUNCTION STRUCTURE

(71) Applicants: Samsung Electronics Co., Ltd., Suwon-si (KR); SEOUL NATIONAL UNIVERSITY R&DB FOUNDATION, Seoul (KR)

(72) Inventors: Huije RYU, Suwon-si (KR); Gwanhyoung LEE, Seoul (KR); Jaewoong JOO, Seoul (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 18/767,488

(22) Filed: Jul. 9, 2024

(30) Foreign Application Priority Data
Feb. 26, 2024 (KR) 10-2024-0027499

(51) Int. Cl. H01L 29/49; H01L 29/45; H01L 29/78

(52) U.S. Cl. CPC H10D 64/667; H10D 30/62; H10D 62/83; H10D 64/62

(57) ABSTRACT

A semiconductor device may include a channel layer on a substrate and including a semiconductor material, and an electrode layer forming an ohmic-contact with the channel layer. The electrode layer may include a metallic transition metal dichalcogenide (TMD) material in contact with the channel layer.

### CROSS-REFERENCE TO RELATED APPLICATION

This application is based on and claims priority under 35 U.S.C. § 119 to Korean Patent Application No. 10-2024-0027499, filed on Feb. 26, 2024, in the Korean Intellectual Property Office, the disclosure of which is incorporated by reference herein in its entirety.

### BACKGROUND

### 1. Field

The present disclosure relates to a semiconductor device and a method of manufacturing an electrode-semiconductor material junction structure.

### 2. Description of the Related Art

As an integration degree of a semiconductor device increases, various structures for reducing an area occupied by each unit device on a plane are being suggested. A transistor is a semiconductor device with an electrical switching function and is used in various integrated circuit devices including memory devices, driving integrated circuits (ICs), logic devices, etc. In order to improve the integration degree of an IC device, a space occupied by a transistor has been rapidly reduced. As such, a channel length of the transistor is reduced, and thicknesses of layers forming the transistor are reduced too. A high contact resistance between a semiconductor material and an electrode limits a current density of a transistor and increases an operating voltage, and thus, there is a need to reduce a contact resistance between a semiconductor material and an electrode.

### SUMMARY

Provided is a method for manufacturing an electrode-semiconductor junction structure, capable of reducing a contact resistance between a semiconductor material and an electrode.

Provided is a semiconductor device having a structure capable of reducing a contact resistance between a semiconductor material in a channel layer and an electrode.

Additional aspects will be set forth in part in the description which follows and, in part, will be apparent from the description, or may be learned by practice of the presented embodiments of the present disclosure.

According to an embodiment, a semiconductor device may include a substrate, a channel layer on the substrate and including a semiconductor material, and an electrode layer forming an ohmic-contact with the channel layer, wherein the electrode layer may include a metallic transition metal dichalcogenide (TMD) material coming into contact with the channel layer.

In some embodiments, the electrode layer including the metallic TMD material may have a thickness of 5 nm to 50 nm.

In some embodiments, the metallic TMD material may include VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

In some embodiments, the semiconductor device may include an anti-oxidation layer on the electrode layer.

In some embodiments, the anti-oxidation layer may include Au, TiN, TaN, Ru, HfO₂, Al₂O₃, ZrO₂, or SiO₂.

In some embodiments, the semiconductor material may include a two-dimensional material.

In some embodiments, the semiconductor material may include a TMD material.

In some embodiments, the semiconductor material may include silicon.

In some embodiments, the channel layer may have a planar structure.

In some embodiments, the channel layer may have a fin structure.

In some embodiments, the channel layer may have a multi-bridge channel structure.

According to an embodiment, a method of manufacturing an electrode-semiconductor material junction structure may include forming a semiconductor layer by depositing a semiconductor material on a substrate, forming a transition metal layer by depositing a transition metal on the semiconductor layer, and forming an electrode layer including a metallic transition metal dichalcogenide (TMD) material by supplying a chalcogen element to the transition metal layer and chalcogenizing the transition metal layer.

In some embodiments, the transition metal may include Mo, Nb, Pd, Pt, Ta, Ti, V, or W.

In some embodiments, the chalcogen element may include S, Se, or Te.

In some embodiments, the metallic TMD material may include VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

In some embodiments, the method may include, before the forming the electrode layer, forming an anti-oxidation layer on the transition metal layer.

In some embodiments, the anti-oxidation layer may include Au, TiN, TaN, Ru, HfO₂, Al₂O₃, ZrO₂, or SiO₂.

In some embodiments, the semiconductor layer may include a two-dimensional material.

In some embodiments, the semiconductor layer may include a TMD material.

In some embodiments, the semiconductor layer may include silicon.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view of an electrode-semiconductor material junction structure according to an embodiment;

FIG. 2 is a cross-sectional view of an electrode-semiconductor material junction structure according to an embodiment;

FIGS. 3A to 3D are diagrams illustrating a method of manufacturing the electrode-semiconductor material junction structure of FIG. 1, according to an embodiment;

FIGS. 4A to 4C are diagrams illustrating a method of manufacturing the electrode-semiconductor material junction structure of FIG. 2, according to an embodiment;

FIG. 5 is a schematic cross-sectional view of a semiconductor device according to an embodiment;

FIGS. 6A, 6B, and 6C are schematic cross-sectional views of semiconductor devices according to example embodiments;

FIG. 7 is a graph showing a source-drain current versus a change in a gate voltage in a field effect transistor (FET) adopting a metal electrode;

FIG. 8 is a graph showing a source-drain current according to a change in a gate voltage in an FET adopting an electrode including a metallic transition metal dichalcogenide (TMD) material;

FIG. 9 is a schematic perspective view of a semiconductor device according to an embodiment; and

FIG. 10 is a schematic partially-cut perspective view of a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the present disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, one or more embodiments will be described in detail with reference to accompanying drawings. In the drawings, like reference numerals denote like components, and sizes of components in the drawings may be exaggerated for convenience of explanation. The embodiments of the present disclosure are capable of various modifications and may be embodied in many different forms.

When a layer, a film, a region, or a panel is referred to as being “on” another element, it may be directly on/under/at left/right sides of the other layer or substrate, or intervening layers may also be present. An expression used in the singular encompasses the expression of the plural, unless it has a clearly different meaning in the context. It will be further understood that when a portion is referred to as “comprising” another component, the portion may not exclude another component but may further comprise another component unless the context states otherwise.

The use of the term of “the above-described” and similar indicative terms may correspond to both the singular forms and the plural forms. Also, the steps of all methods described herein may be performed in any suitable order unless otherwise indicated herein or otherwise clearly contradicted by context.

Also, the terms “ . . . unit”, “ . . . module” used herein specify a unit for processing at least one function or operation, and this may be implemented with hardware or software or a combination of hardware and software.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of any and all examples, or example language provided herein, is intended merely to better illuminate the present disclosure and does not pose a limitation on the scope of the present disclosure unless otherwise claimed.

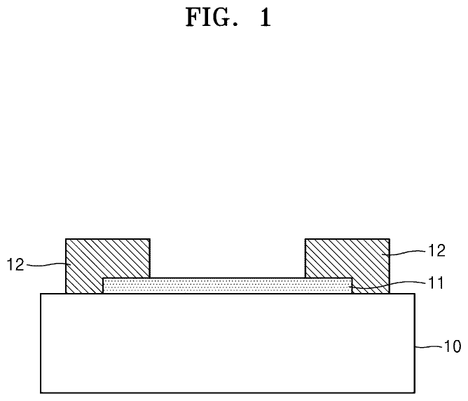

FIG. 1 is a schematic cross-sectional view of an electrode-semiconductor material junction structure according to an embodiment. Referring to FIG. 1, a semiconductor layer 11 including a semiconductor material and an electrode layer 12 forming an ohmic-junction with the semiconductor layer 11 are shown. The electrode layer 12 may include a metallic transition metal dichalcogenide (TMD) material forming an ohmic-junction by coming into contact with the semiconductor layer 11.

The semiconductor layer 11 may be formed on a surface of a substrate 10. The substrate 10 may include an insulating substrate. The substrate 10 may include a semiconductor substrate on which an insulating layer (not shown) is formed. The semiconductor substrate may include, for example, Si, Ge, SiGe, a group III-V semiconductor material, etc. The substrate 10 may include, for example, a silicon substrate on which a silicon oxide layer is formed. The semiconductor layer 11 is an active layer of a semiconductor device. The semiconductor layer 11 may include a semiconductor material. Kinds of the semiconductor material are not particularly limited. For example, the semiconductor material may include silicon. The semiconductor material may include an oxide semiconductor material capable of adjusting electrical conductivity through doping. An oxide semiconductor material may include, for example, silicon oxide semiconductor, metal oxide semiconductor, etc. The semiconductor material may include a two-dimensional semiconductor material. The two-dimensional semiconductor material may include, for example, a TMD material.

The TMD material may include, for example, one transition metal from Mo, W, Nb, V, Ta, Ti, Zr, Hf, Tc, and Re, and one chalcogen element from S, Se, and Te. The TMD material may be expressed as, for example, MX₂, where M denotes a transition metal and X denotes a chalcogen element. For example, M may include Mo, W, Nb, V, Ta, Ti, Zr, Hf, Tc, Re, etc., and X may include S, Se, Te, etc. Therefore, the TMD material may include, for example, MoS₂, MoSe₂, MoTe₂, WS₂, WSe₂, WTe₂, ZrS₂, ZrSe₂, HfS₂, HfSe₂, NbSe₂, ReSe₂, etc.

However, above-described materials are examples, and other materials may be used as the TMD material. For example, the TMD material may not be expressed as MX₂. In this case, for example, the TMD material may include CuS that is a compound of Cu, that is, transition metal, and S, that is, chalcogen element. In addition, the TMD material may be a chalcogenide material including a non-transition metal. The non-transition metal may include, for example, Ga, In, Sn, Ge, Pb, etc. In this case, the TMD material may include a compound of non-transition metal such as Ga, In, Sn, Ge, Pb, etc. and a chalcogen element such as S, Se, and Te. For example, the TMD may include SnSe₂, GaS, GaSe, GaTe, GeSe, In₂Se₃, InSnS₂, etc. When the semiconductor layer 11 includes the TMD material, the TMD material may have a thickness of 0.7 nm to 5 nm.

The semiconductor layer 11 may be doped with a p-type dopant or an n-type dopant. The p-type dopant or the n-type dopant may be doped on the semiconductor layer 11 using an ion implantation or chemical doping method.

The electrode layer 12 may be electrically connected to the semiconductor layer 11. The electrode layer 12 may form an ohmic-junction with the semiconductor layer 11. In general, metal is used as an electrode material forming the electrode layer 12. In this case, a contact resistance may increase due to Fermi level pinning between the metal and the semiconductor material of the semiconductor layer 11. Therefore, during the process of manufacturing the electrode-semiconductor material junction structure, it may be necessary to reduce the Fermi level pinning effect by shielding or reducing chemical reactions between the electrode material and the semiconductor material.

In order to reduce the contact resistance, a method of reducing a metal-induced gap state (MIGS) of the semiconductor material by applying semimetal having low density of state (DOS) as the electrode material may be considered. However, in this state, there is a limitation in available electrode materials, and the semimetal generally has low melting point and may be difficult to be used in post-semiconductor processes for manufacturing the semiconductor device adopting the electrode-semiconductor material junction structure.

As an alternative, a method of changing a deposition condition of metal so as to limit and/or minimize a defect-induced gap state (DIGS) by reducing defects occurring in the semiconductor material during processes of depositing metal may be considered. In this case, there is a limitation in electrode-semiconductor material combinations that are suitable for changing the deposition condition. Also, it may be difficult to commonly apply the metal suitable for changing the deposition condition to the n-channel and p-channel, and thus, the deposition condition has to be changed according to the conductive type of the semiconductor layer 11.

The present disclosure provides an electrode-semiconductor material junction structure capable of reducing the contact resistance. In the electrode-semiconductor material junction structure according to an embodiment, the electrode material forming the electrode layer 12 may include a metallic TMD material. The electrode layer 12 including the metallic TMD material comes into direct contact with the semiconductor layer 11 and forms an electrode material-channel material junction structure. The metallic TMD material has an electrical conductivity that is equivalent to that of metal.

For example, the metallic TMD material may include, for example, one transition metal from Mo, Nb, Pd, Pt, Ta, Ti, V, and W, and one chalcogen element from S, Se, and Te. Therefore, for example, the metallic TMD material may include VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

The metallic TMD material does not have a dangling bond on an interfacial surface, and thus, Fermi level pinning does not occur between the TMD and the semiconductor material. Therefore, the Fermi level pinning between the electrode and the semiconductor material and the increase in the contact resistance may be reduced or prevented. When the semiconductor layer 11 is formed of the TMD material, both the semiconductor layer 11 and the electrode layer 12 do not have the dangling bond, and thus, the Fermi level pinning between the electrode and the semiconductor material and the increase in the contact resistance may be further reduced or prevented. Also, the metallic TMD material having an appropriate work function according to the conductive type of the semiconductor layer 11 may be used as the electrode material. Therefore, complexity and difficulty in the semiconductor processes for manufacturing the electrode-semiconductor material junction structure may be reduced.

The electrode layer 12 may have a thickness that is greater than or equal to the thickness of the semiconductor layer 11. For example, the thickness of the electrode layer 12 may be 5 nm or greater. The thickness of the electrode layer 12 may be, for example, 50 nm or less (e.g., 5 nm to 50 nm).

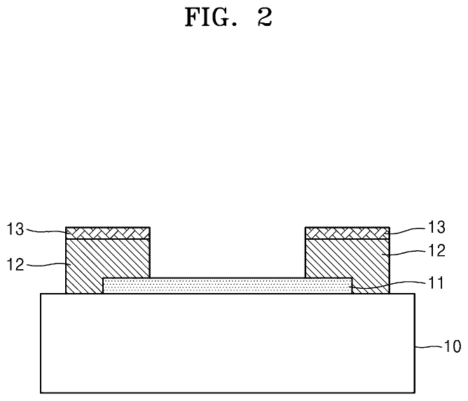

FIG. 2 is a cross-sectional view of an electrode-semiconductor material junction structure according to an embodiment. The electrode-semiconductor material junction structure of FIG. 2 according to the embodiment may be different from the electrode-semiconductor material junction structure of FIG. 1, in view of further including an anti-oxidation layer 13. Therefore, the same elements are denoted by the same reference numerals, and repeated descriptions thereof are omitted.

Referring to FIG. 2, the electrode-semiconductor material junction structure may include the anti-oxidation layer 13. The anti-oxidation layer 13 is formed on the electrode layer 12. The anti-oxidation layer 13 at least partially covers the electrode layer 12. For example, the anti-oxidation layer 13 of FIG. 2 covers an upper surface of the electrode layer 12. The anti-oxidation layer 13 prevents oxidation of the transition metal during the processes of forming the electrode-semiconductor material junction structure. As described later, the electrode layer 12 is formed by chalcogenizing a transition metal layer. The metallic TMD material may have a layered structure. The anti-oxidation layer 13 covers the transition metal layer so that the electrode layer 12 may be formed to have a stabilized layered structure during the process of chalcogenizing the transition metal. Accordingly, a stabilized van der walls interface may be formed between the semiconductor layer 11 and the electrode layer 12.

The anti-oxidation layer 13 may include Au, but is not limited thereto. The anti-oxidation layer 13 may include TiN, TaN, or Ru and various combinations thereof. The anti-oxidation layer 13 may include various metal oxides. The metal oxide may include, for example, HfO₂, Al₂O₃, ZrO₂, or SiO₂.

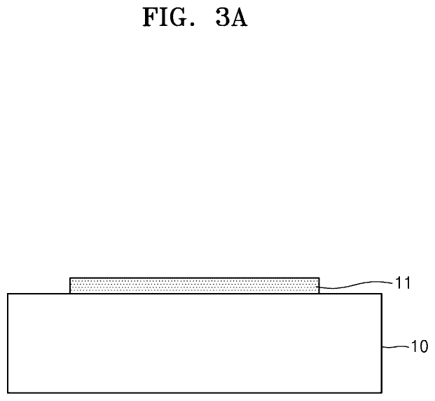

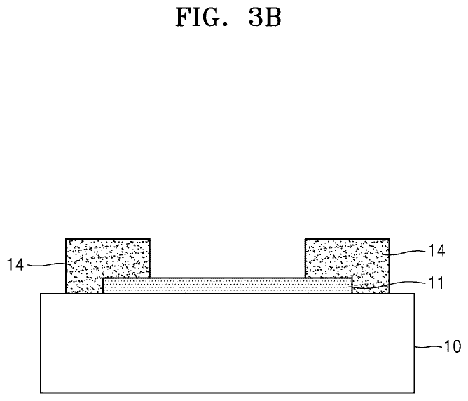

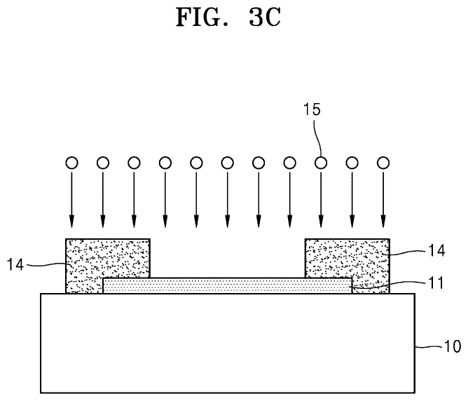

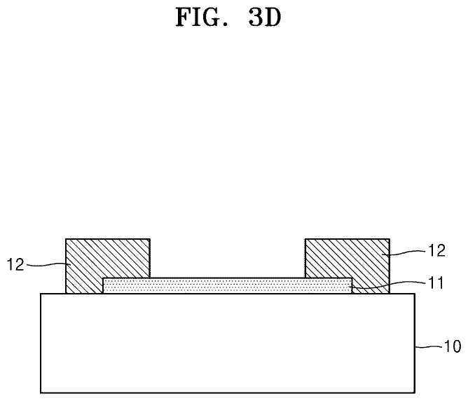

FIGS. 3A to 3D are diagrams illustrating a method of manufacturing the electrode-semiconductor material junction structure according to an embodiment. Referring to FIGS. 3A to 3D, a method of manufacturing the electrode-semiconductor material junction structure of FIG. 1 according to an example is described below.

First, as shown in FIG. 3A, the semiconductor material is deposited on the substrate 10 to form the semiconductor layer 11. As described above, the substrate 10 may include an insulating substrate or a semiconductor substrate on which an insulating layer (not shown) is formed. For example, the semiconductor material may include silicon, oxide semiconductor material such as silicon oxide semiconductor or metal oxide semiconductor, etc., and a two-dimensional semiconductor material such as TMD material, etc. There is no particular limitation in the method of forming the semiconductor layer 11 on the substrate 10. The semiconductor layer 11 may be formed by a chemical vapor deposition (CVD), a plasma enhanced chemical vapor deposition (PECVD), metal organic chemical vapor deposition (MOCVD), atomic layer deposition (ALD), etc., or a combination of two or more thereof, according to the kind of the semiconductor material.

Next, as shown in FIG. 3B, the transition metal is deposited on the semiconductor layer 11 to form a transition metal layer 14. For example, the transition metal may include Mo, Nb, Pd, Pt, Ta, Ti, V, or W. There is no particular limitation in the method of forming the transition metal layer 14.

Next, the transition metal layer 14 is chalcogenized to form the electrode layer 12 including the metallic TMD material. As shown in FIG. 3C, precursors 15 including chalcogen element are supplied. The chalcogen element may include, for example, S, Se, or Te. A reaction temperature may be, for example, 300° C. to 600° C. The metallic TMD material is generated when the chalcogen element included in the precursor 15 and the transition metal in the transition metal layer 14 react with each other. The metallic TMD material may include VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂. A catalytic gas may be supplied along with the precursor 15. The catalytic gas may accelerate the reaction between the chalcogen element and the transition metal by isolating the chalcogen element from the precursor 15. Accordingly, as shown in FIG. 3D, the electrode layer 12 including the metallic TMD material may be formed on the semiconductor layer 11.

As described above, because the metallic TMD material does not have the dangling bond on the interfacial surface, the Fermi level pinning between the semiconductor layer 11 and the electrode layer 12 and the increase in the contact resistance may be reduced or prevented. When the semiconductor layer 11 is formed of the TMD material, both the semiconductor layer 11 and the electrode layer 12 do not include the dangling bond, and thus, the increase in the contact resistance may be further reduced or prevented. Also, defects of the TMD material in the semiconductor layer 11 may be cured during the process of chalcogenizing the transition metal layer 14. Therefore, the DIGS may be reduced, and the contact resistance may be further reduced. Also, because the metallic TMD material having an appropriate work function may be used as the electrode material according to the conductive type of the semiconductor layer 11, the complexity and difficulty of the semiconductor processes for manufacturing the electrode-semiconductor material junction structure may be reduced.

A method of forming the electrode layer 12 by simultaneously supplying the transition metal precursor and the chalcogen element so as to form the metallic TMD material layer may be considered. In this case, it may be difficult to pattern the region where the electrode layer 12 is to be formed. When the metallic TMD material is formed by simultaneously supplying the transition metal source and chalcogen element source, a nucleation region of the metallic TMD material needs to be restricted. To this end, a region where the metallic TMD material is to be formed has to be patterned through a lithography process, etc. in advance, and because the process for forming the electrode-semiconductor material junction structure is a high-temperature process, it is difficult to form a patterning layer that may be applied to the high-temperature process. According to the manufacturing method of the present disclosure, the transition metal layer 14 is patterned in advance by, for example, a lithography process, and the chalcogenizing is performed. Thus, the electrode layer 12 including the patterned metallic TMD material may be formed. The manufacturing method according to the present disclosure has processing advantages, that is, may be applied to the current semiconductor processes.

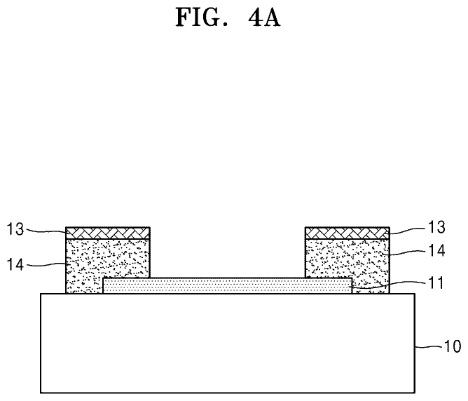

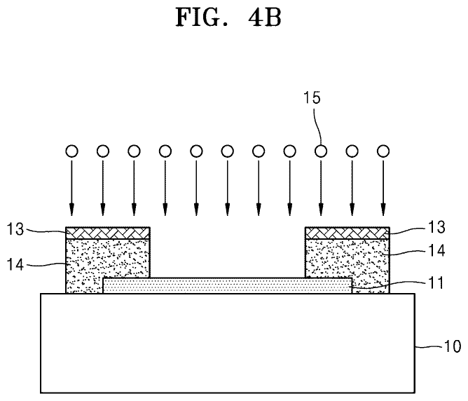

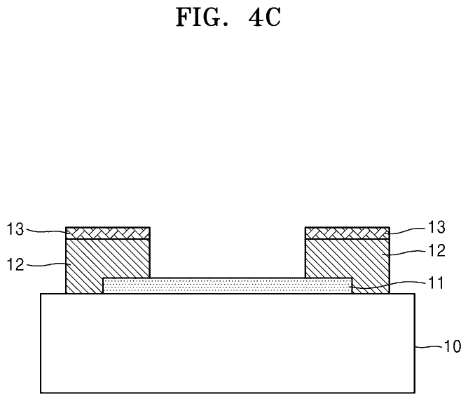

FIGS. 4A to 4C are diagrams illustrating a method of manufacturing the electrode-semiconductor junction structure according to an embodiment. Referring to FIGS. 3A, 3B, and 4A to 4C, a method of manufacturing the electrode-semiconductor material junction structure of FIG. 2 according to an example is described below.

As described above with reference to FIGS. 3A and 3B, the semiconductor material is deposited on the substrate 10 to form the semiconductor layer 11, and the transition metal is deposited on the semiconductor layer 11 to form the transition metal layer 14.

Next, as shown in FIG. 4A, the anti-oxidation layer 13 is formed on the transition metal layer 14. The anti-oxidation layer 13 may cover the upper surface of the transition metal layer 14, but is not limited thereto. The anti-oxidation layer 13 may cover the upper and side surfaces of the transition metal layer 14. The anti-oxidation layer 13 may include Au, but is not limited thereto. The anti-oxidation layer 13 may include TiN, TaN, or Ru and various combinations thereof. The anti-oxidation layer 13 may include various metal oxides. The metal oxide may include, for example, HfO₂, Al₂O₃, ZrO₂, or SiO₂. In the embodiment, the anti-oxidation layer 13 may include, for example, Au.

Next, the transition metal layer 14 is chalcogenized to form the electrode layer 12 including the metallic TMD material. As shown in FIG. 4B, the precursor 15 including the chalcogen element is supplied to chalcogenize the transition metal of the transition metal layer 14. Accordingly, as shown in FIG. 4C, the electrode layer 12 including the metallic TMD material may be formed on the semiconductor layer 11. The metallic TMD material may have a layered structure. The anti-oxidation layer 13 covers the transition metal layer so that the electrode layer 12 may be formed to have a stabilized layered structure during the process of chalcogenizing the transition metal. Accordingly, a stabilized van der walls interface may be formed between the semiconductor layer 11 and the electrode layer 12. The above descriptions with reference to FIGS. 3C and 3D are applied to FIGS. 4B and 4C.

The above electrode-semiconductor material junction structure may be applied to a junction structure between an active layer and an electrode layer in various semiconductor devices, for example, a junction structure between a channel layer and an electrode layer in a field-effect transistor (FET).

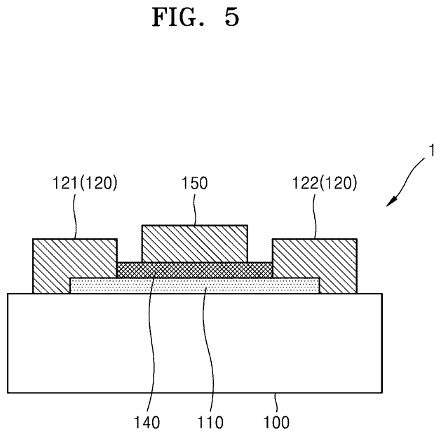

FIG. 5 is a schematic cross-sectional view of a semiconductor device 1 according to an embodiment. The semiconductor device 1 according to the embodiment may include, for example, an FET. Referring to FIG. 5, the semiconductor device 1 includes a substrate 100, a channel layer 110 including a semiconductor material and formed on the substrate 100, and an electrode layer 120 forming an ohmic-contact with the channel layer 110. A gate electrode layer 150 is disposed on the channel layer 110 with a gate insulating layer 140 interposed therebetween. For example, the electrode layer 120 may include a source electrode 121 and a drain electrode 122. The electrode layer 120 may include a metallic TMD material that comes into contact with the channel layer 110 and forms an ohmic-contact.

The substrate 100 may include an insulating substrate. The substrate 100 may include a semiconductor substrate on which the insulating layer is formed. The semiconductor substrate may include, for example, Si, Ge, SiGe, a group III-V semiconductor material, etc. The substrate 100 may include, for example, a silicon substrate having a silicon oxide layer formed on the surface thereof, but is not limited thereto. A metallization layer (not shown) may be provided on the substrate 100.

The channel layer 110 may be formed on the substrate 100. In the semiconductor device 1 according to the present disclosure, the channel layer 110 has a planar structure. The channel layer 110 may include a semiconductor material. The semiconductor material may include, for example, silicon. The semiconductor material may include an oxide semiconductor material capable of adjusting electrical conductivity through doping. An oxide semiconductor material may include, for example, silicon oxide semiconductor, metal oxide semiconductor, etc. The semiconductor material may include a two-dimensional semiconductor material. The two-dimensional semiconductor material may include, for example, a TMD material.

The two-dimensional material, e.g., the TMD material, is used in the channel layer 110 in order to implement a short channel length when the semiconductor device 1 is applied to the FET. The channel length denotes a length of the channel in a direction that the source electrode and the drain electrode are away from each other. Recently, the channel length has been reduced according to a miniaturization trend of electronic apparatuses. It is known that as the channel length become shorter, issues due to a short channel effect occur. Reducing a thickness of the channel may effectively reduce the channel length and may limit and/or prevent the above issues. In other words, as the thickness of the channel is reduced, a minimum channel length that may be implemented may be set to be short. The two-dimensional semiconductor material, e.g., the TMD material, has excellent electrical property, and may maintain high mobility without largely changing the characteristics thereof even when the thickness is reduced to a nano-scale. That is, the TMD material is a two-dimensional material formed through van der walls interaction, and may have a device property only with one layer. The TMD material may have a monolayer or multilayer structure. Each layer in the TMD material forming the channel may have a thickness of an atomic level. For example, the thickness of the channel layer 110 may be about 10 nm or less, 5 nm or less, or 3 nm or less. The thickness of the channel layer 110 is not limited thereto, but may be further reduced. However, one or more embodiments are not limited to the above examples. As the thickness of the channel layer 110 is reduced, the length of the channel layer 110 may be reduced. For example, the channel layer 110 may be formed of the TMD material in one to ten layers.

The TMD material may include, for example, one transition metal from Mo, W, Nb, V, Ta, Ti, Zr, Hf, Tc, and Re, and one chalcogen atom from S, Se, and Te. The TMD may be expressed as, for example, MX₂, where M denotes a transition metal and X denotes a chalcogen element. For example, M may include Mo, W, Nb, V, Ta, Ti, Zr, Hf, Tc, Re, etc., and X may include S, Se, Te, etc. Therefore, the TMD material may include, for example, MoS₂, MoSe₂, MoTe₂, WS₂, WSe₂, WTe₂, ZrS₂, ZrSe₂, HfS₂, HfSe₂, NbSe₂, ReSe₂, etc.

However, the above-described materials are non-limiting examples, and other materials may be used as the TMD material. For example, the TMD may not be expressed as MX₂. In this case, for example, the TMD may include CuS that is a compound of Cu, that is, transition metal, and S, that is, chalcogen element. In addition, the TMD may be a chalcogenide material including a non-transition metal. The non-transition metal may include, for example, Ga, In, Sn, Ge, Pb, etc. In this case, the TMD material may include a compound of non-transition metal such as Ga, In, Sn, Ge, Pb, etc. and a chalcogen element such as S, Se, and Te. For example, the TMD material may include SnSe₂, GaS, GaSe, GaTe, GeSe, In₂Se₃, InSnS₂, etc.

The channel layer 110 may be, for example, a p-channel or an n-channel. To this end, the channel layer 110 may be doped with a p-type dopant or an n-type dopant, as necessary. The p-type dopant or the n-type dopant may be doped on the channel layer 110 by an ion implantation or chemical doping method.

When the channel layer 110 includes the TMD material, the TMD material may have a thickness of 0.7 nm to 5 nm.

The source electrode 121 and the drain electrode 122 may be away from each other in the lengthwise direction of the channel layer 110. The source electrode 121 may be electrically connected to one end portion of the channel layer 110 in the lengthwise direction. The drain electrode 122 may be electrically connected to the other end of the channel layer 110 in the lengthwise direction.

The gate electrode 150 may be located between the source electrode 121 and the drain electrode 122 in the lengthwise direction of the channel layer 110. The gate electrode 150 may be spaced apart from the source electrode 121 and the drain electrode 122. The gate electrode 150 faces the channel layer 110 with the gate insulating layer 140 disposed therebetween. The gate electrode 150 may include a metal material or a conductive oxide. The metal material may include at least one selected from the group consisting of, for example, Au, Ti, TiN, TaN, W, Mo. WN, Pt, and Ni. The conductive oxide may include, for example, indium tin oxide (ITO), indium zinc oxide (IZO), etc. The gate electrode 150 may include polysilicon or single-crystalline silicon. The gate insulating layer 140 may include, for example, a metal oxide dielectric substance. The metal oxide dielectric substance may be an oxide material of, for example, Al, La, Ti, Zr, Hf, Mg, Ge, Y, Lu, or Sr. The gate insulating layer 140 may include silicon oxide or silicon nitride.

As such, the semiconductor device 1 having the FET structure may be formed.

As miniaturization of the FET has been progressed, various research for reducing a short channel effect and improving a gate controllability has been conducted. A high contact resistance between the semiconductor material forming the channel layer 110 and the electrode layer 120 may restrict the current density and increase an operating voltage. Therefore, in miniaturizing the FET, it may be important to reduce the contact resistance between the semiconductor material (hereinafter, channel material) forming the channel layer 110 and the electrode layer 120 (hereinafter, electrode material). In general, metal is used as the electrode material. In this case, a contact resistance may increase due to Fermi level pinning between the metal and the channel material. Therefore, during the processes of manufacturing the semiconductor device 1, it may be necessary to reduce the Fermi level pinning by blocking or reducing the chemical reaction between the channel material and the electrode material.

In order to reduce the contact resistance, a method of reducing a metal-induced gap state (MIGS) of the channel material may be considered by applying semimetal having low density of state (DOS) as the electrode material. However, in this case, there is a limitation in the available electrode materials, and semimetal generally has a low melting point and is difficult to be used in the post-semiconductor processes.

As an alternative, a method of changing a deposition condition of metal may be considered so as to minimize a DIGS by reducing defects occurring in the channel material during processes of depositing metal. In this case, there is a limitation in metal-channel material combinations that are suitable for changing the deposition condition. Also, it may be difficult to commonly apply the metal suitable for changing the deposition condition to the n-channel and p-channel, and thus, the deposition condition has to be changed according to the conductive type of the channel layer 110.

The semiconductor device 1 according to the present disclosure may adopt the electrode-semiconductor material junction structure described above in order to reduce the contact resistance between the electrode layer 120 and the channel layer 110. In the semiconductor device 1 according to an embodiment, the electrode material forming the electrode material 120 includes the metallic TMD material. The electrode material 120 including the metallic TMD material comes into direct contact with the channel layer 110 and forms the electrode-semiconductor material junction structure.

The metallic TMD material has an electrical conductivity that is equivalent to that of metal. For example, the metallic TMD may include, for example, one transition metal from Mo, Nb, Pd, Pt, Ta, Ti, V, and W, and one chalcogen atom from S, Se, and Te. Therefore, for example, the metallic TMD material may include VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

The metallic TMD material does not have a dangling bond on an interfacial surface, and thus, Fermi level pinning does not occur between the TMD and the channel material. Therefore, the Fermi level pinning between the electrode material-channel material and the increase in the contact resistance may be reduced or prevented. When the channel layer 110 is formed of the TMD material, the channel layer 110 and the electrode layer 120 do not have the dangling bond, and thus, the Fermi level pinning between the electrode material-channel material and the increase in the contact resistance may be further reduced or prevented. Also, the metallic TMD material having an appropriate work function according to the conductive type of the channel layer 110 may be used as the electrode material. Therefore, complexity and difficulty in the semiconductor processes for manufacturing the semiconductor device 1 may be reduced.

The electrode layer 120 may have a thickness that is greater than or equal to the thickness of the channel layer 110. For example, the thickness of the electrode layer 120 may be 5 nm or greater. The thickness of the electrode layer 120 may be, for example, 50 nm or less.

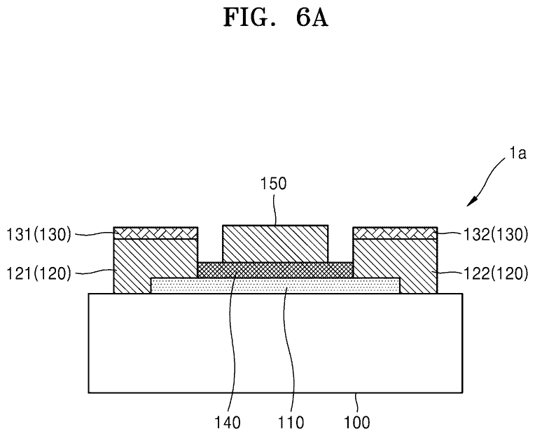

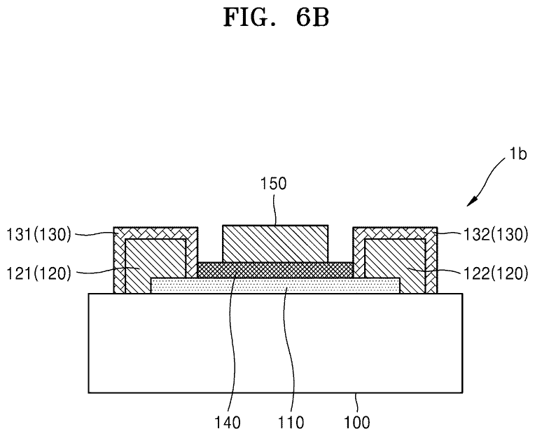

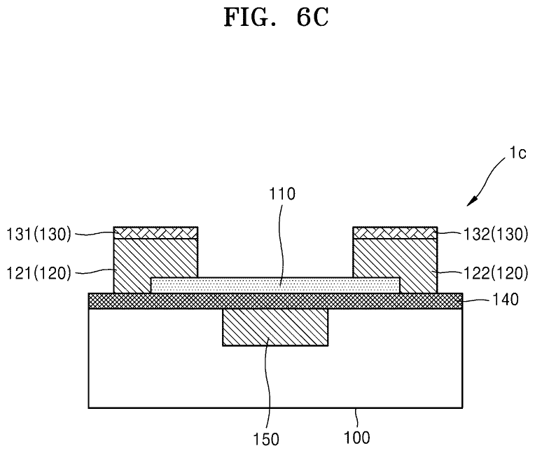

FIGS. 6A, 6B, and 6C are schematic cross-sectional views of semiconductor devices 1a, 1b, and 1c according to example embodiments. The semiconductor devices 1a and 1b according to the embodiment shown in FIGS. 6A and 6B differ from the semiconductor device 1 according to the embodiment of FIG. 5, in view of further including an anti-oxidation layer 130. Therefore, the same elements are denoted by the same reference numerals, and repeated descriptions thereof are omitted.

Referring to FIGS. 6A and 6B, in example embodiments, the semiconductor devices 1a and 1b may include the anti-oxidation layer 130. The anti-oxidation layer 130 is formed on the electrode layer 120. The anti-oxidation layer 130 at least partially covers the electrode layer 120. For example, the anti-oxidation layer 130 of the semiconductor device 1a of FIG. 6A covers an upper surface of the electrode layer 120. For example, the anti-oxidation layer 130 of the semiconductor device 1b of FIG. 6B covers upper and side surfaces of the electrode layer 120. The anti-oxidation layer 130 may include first and second anti-oxidation layers 131 and 132 respectively formed on the source electrode 121 and the drain electrode 122.

As described above, the electrode layer 120 may be formed by chalcogenizing the transition metal layer. The metallic TMD material may have a layered structure. The anti-oxidation layer 130 covers the transition metal layer so that the electrode layer 120 may be formed to have a stabilized layered structure during the process of chalcogenizing the transition metal. Accordingly, a stabilized van der walls interface may be formed between the channel layer 110 and the electrode layer 120. The anti-oxidation layer 130 may include Au, but is not limited thereto. The anti-oxidation layer 130 may include TiN, TaN, or Ru and various combinations thereof. The anti-oxidation layer 130 may include various metal oxides. The metal oxide may include, for example, HfO₂, Al₂O₃, ZrO₂, or SiO₂.

The semiconductor devices 1, 1a, and 1b described above with reference to FIGS. 5, 6A, and 6B each may be modified to provide a bottom-gate semiconductor device. For example, FIG. 6C illustrates a semiconductor device 1c that is a bottom-gate modification of the semiconductor device 1a in FIG. 6A, but the semiconductor devices 1 and 1b described in FIGS. 5 and 6B also may be modified to provide bottom-gate semiconductor devices.

In FIG. 6C, the gate electrode 150 may be formed in a trench that is recessed from an upper surface of the substrate 100 and the gate insulating layer 140 may be formed on an upper surface of the gate electrode 150. The source electrode 121, channel layer 110, and drain electrode 122 may be formed on the gate insulating layer 140. An anti-oxidation layer 130 of the semiconductor device 1c may cover upper surfaces of the source electrode 121 and the drain electrode 122. Although not illustrated in FIG. 6C, the anti-oxidation layer 130 may also cover side surfaces of the source electrode 121 and the drain electrode 122 like as shown in FIG. 6B.

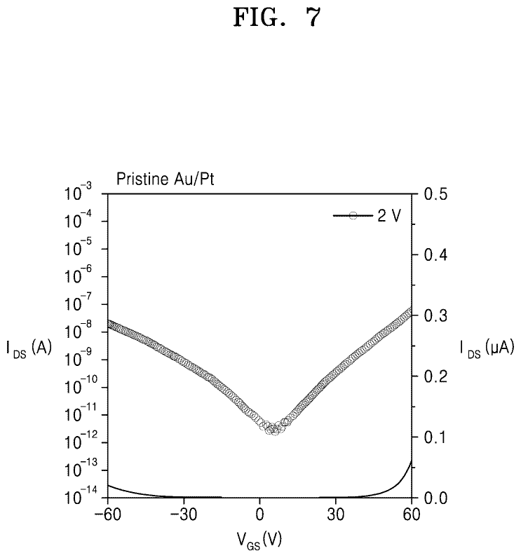

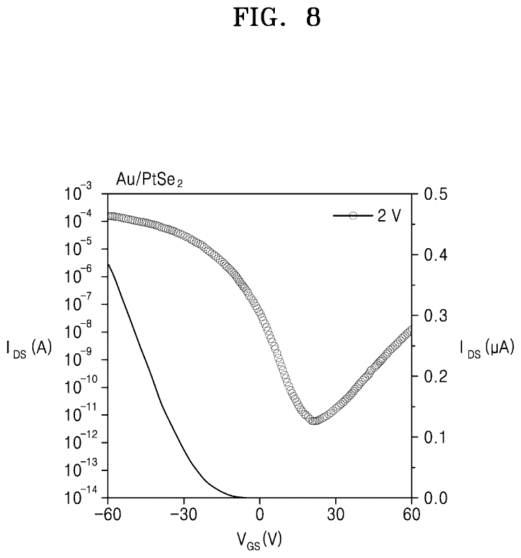

FIG. 7 is a graph showing a source-drain current I_{DS} versus a change in a gate voltage V_{GS} in an FET adopting a metal electrode. FIG. 8 is a graph showing a source-drain current I_{DS} according to a change in a gate voltage V_{GS} in an FET adopting an electrode including a metallic transition metal dichalcogenide material. In FIGS. 7 and 8, the semiconductor material of the channel layer is WSe₂. In FIG. 7, Au/Pt electrode is applied as the electrode. In FIG. 8, Au/PtSe₂ is applied as the electrode. PtSe₂ is formed by depositing Pt on a WSe₂-channel layer and providing precursors including Se in order to chalcogenize Pt. Referring to FIGS. 7 and 8, when PtSe₂ is used as the electrode, the Fermi level pinning does not occur in the WSe₂-channel layer as compared with the case in which Pt is used as the electrode, and thus, a threshold voltage moves to the positive voltage. Also, the on-current level relatively increases.

The embodiment of the semiconductor device 1 is not limited to the FET including the channel layer 110 having the planar structure. For example, the channel layer may have a fin-structure.

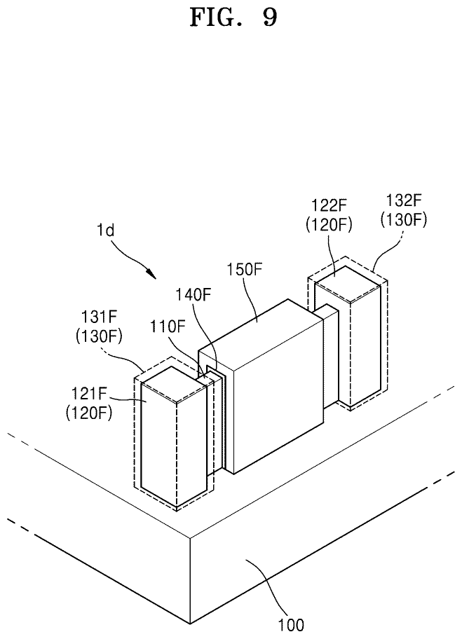

FIG. 9 is a schematic perspective view of a semiconductor device 1d according to an embodiment. Referring to FIG. 9, the semiconductor device 1d includes the substrate 100, a channel layer 110F including a semiconductor material and formed on the substrate 100, and an electrode layer 120F forming an ohmic-contact with the channel layer 110F. A gate electrode layer 150F is disposed on the channel layer 110F with a gate insulating layer 140F interposed therebetween. The electrode layer 120F ohmic-contacts the channel layer 110F. For example, the electrode layer 120F may include a source electrode 121F and a drain electrode 122F. The source electrode 121F and the drain electrode 122F respectively form ohmic-contacts with opposite end portions of the channel layer 110F in the lateral direction. The electrode layer 120F may include a metallic TMD material that comes into contact with the channel layer 110F and forms an ohmic-contact. The gate electrode layer 150F may be spaced apart from the source electrode 121F and the drain electrode 122F and the gate electrode layer 150F may be between the source electrode 121F and the drain electrode 122F.

As indicated by dashed lines in FIG. 9, the electrode layer 120F may be at least partially covered by an anti-oxidation layer 130F. For example, the source electrode 121F and the drain electrode 122F may be covered respectively by the anti-oxidation layers 131F and 132F. The anti-oxidation layers 131F and 132F may cover upper surfaces of the source electrode 121F and the drain electrode 122F, or may cover upper and side surfaces of the source and drain electrodes 121F and 122F.

The above descriptions about the channel layer 110, the electrode layer 120, the anti-oxidation layer 130, the gate insulating layer 140, and the gate electrode 150 are applied to the channel layer 110F, the electrode layer 120F, the anti-oxidation layer 130F, the gate insulating layer 140F, and the gate electrode 150F.

The channel layer 110F may have a fin-structure. The channel layer 110F has a fin-shape extending vertically from the surface of the substrate 100. The gate electrode 150F faces three surfaces of the channel layer 110F with the gate insulating layer 140F disposed therebetween. The semiconductor device 1d of the above type is referred to as a FinFET.

Unlike the FET of the planar structure, in which the gate electrode faces one surface of the channel, in the FinFET, three surfaces of the channel face the gate electrode. Therefore, a leakage current may be reduced, and the FET of smaller size may be implemented. Also, because the leakage current characteristic is improved, a gate controllability may be improved.

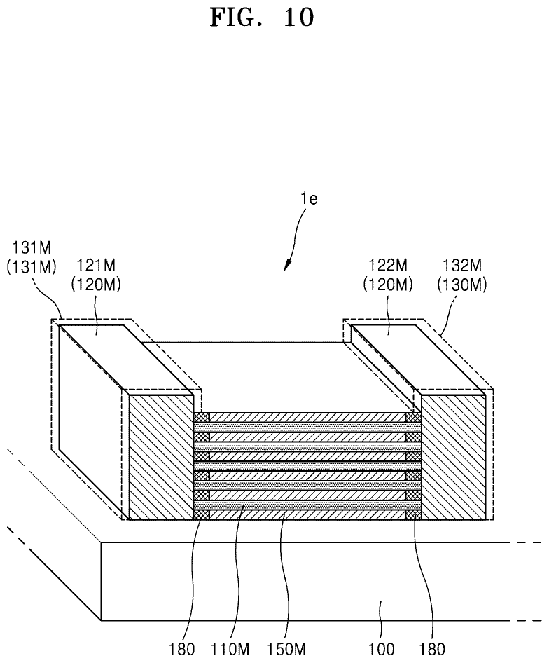

FIG. 10 is a schematic partially-cut perspective view of a semiconductor device 1e according to an embodiment. Referring to FIG. 10, the semiconductor device 1e may include the substrate 100, a plurality of channel layers 110M including a semiconductor material and formed on the substrate 100, and an electrode layer 120M forming an ohmic-contact with the plurality of channel layers 110M. A gate electrode layer 150M is arranged to face the plurality of channel layers 110M with a gate insulating layer (not shown) disposed therebetween. For example, the electrode layer 120M may include a source electrode 121M and a drain electrode 122M. The source electrode 121M and the drain electrode 122M respectively form ohmic-contacts with opposite end portions of the plurality of channel layers 110M in the lateral direction. The electrode layer 120M may include a metallic TMD material that comes into contact with the plurality of channel layers 110M and forms an ohmic-contact.

As indicated by dashed lines in FIG. 10, the electrode layer 120M may be at least partially covered by an anti-oxidation layer 130M. For example, the source electrode 121M and the drain electrode 122M may be covered respectively by the anti-oxidation layers 131M and 132M. The anti-oxidation layers 131M and 132M may cover upper surfaces of the source electrode 121M and the drain electrode 122M, or may cover upper and side surfaces of the source and drain electrodes 121M and 122M.

The above descriptions about the channel layer 110, the electrode layer 120, the anti-oxidation layer 130, the gate insulating layer 140, and the gate electrode 150 are applied to the channel layer 110M, the electrode layer 120M, the anti-oxidation layer 130M, the gate insulating layer (not shown), and the gate electrode 150M.

The plurality of channel layers 110M have a multi-bridge channel structure. The plurality of channel layers 110M extend in a direction parallel to the surface of the substrate 100 and are stacked in a direction perpendicular to the surface of the substrate 100. The plurality of channel layers 100M are formed in nano-sheet types. The plurality of channel layers 110M pass through the gate electrode 150M. Although not shown in the drawings, the gate insulating layer (not shown) is disposed between the plurality of channel layers 110F and the gate electrode 150M. The gate electrode 150M faces four surfaces of each of the plurality of channel layers 110M. The semiconductor device 1e in the above type is referred to as a multi-bridge channel field effect transistor (MBCFET).

Unlike the FET of the planar structure, in which the gate electrode faces one surface of the channel, in the MBCFET, four surfaces of the channel face the gate electrode. Also, the channel is formed in the nano-sheet type unlike a gate all around (GAA)-FET having a channel of a nano-wire type, and thus, a facing area between the channel and the gate may be further increased as compared with the GAA-FET. Therefore, the gate controllability may be further improved.

The gate electrode layer 150M may be spaced apart from the source electrode 121M and the drain electrode 122M and the gate electrode layer 150M may be between the source electrode 121M and the drain electrode 122M. The semiconductor device 1e may include spacer layers 180 between the source electrode 121M and a first side of the gate electrode 150M facing the source electrode 121M. The semiconductor device 1e may include spacer layers 180 between the drain electrode 122M and a second side of the gate electrode 150M facing the drain electrode 122M. The spacer layers 180 may include an insulating material, such as silicon oxide, silicon nitride, or silicon oxynitride, but are not limited thereto. The spacer layers 180 may be spaced apart from each other in a vertical direction.

According to the semiconductor device of the embodiments, the metallic TMD material is adopted as the electrode material, and thus, a contact resistance between the channel layer and the electrode layer may be reduced.

According to the embodiments of the electrode-semiconductor material junction structure described above, the electrode layer including the metallic TMD material is formed by chalcogenizing the transition metal layer on the semiconductor layer, and accordingly, the contact resistance between the electrode-semiconductor material may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
a channel layer on the substrate and including a semiconductor material; and
an electrode layer forming an ohmic-contact with the channel layer,
wherein the electrode layer includes a metallic transition metal dichalcogenide (TMD) material in contact with the channel layer.

2. The semiconductor device of claim 1, wherein the electrode layer including the metallic TMD material has a thickness of 5 nm to 50 nm.

3. The semiconductor device of claim 1, wherein the metallic TMD material includes VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

4. The semiconductor device of claim 1, further comprising:
an anti-oxidation layer on the electrode layer.

5. The semiconductor device of claim 4, wherein the anti-oxidation layer includes Au, TiN, TaN, Ru, HfO₂, Al₂O₃, ZrO₂, or SiO₂.

6. The semiconductor device of claim 1, wherein the semiconductor material includes a two-dimensional material.

7. The semiconductor device of claim 1, wherein the semiconductor material includes a TMD material.

8. The semiconductor device of claim 1, wherein the semiconductor material includes silicon.

9. The semiconductor device of claim 1, wherein the channel layer has a planar structure.

10. The semiconductor device of claim 1, wherein the channel layer has a fin structure.

11. The semiconductor device of claim 1, wherein the channel layer has a multi-bridge channel structure.

12. A method of manufacturing an electrode-semiconductor material junction structure, the method comprising:
forming a semiconductor layer by depositing a semiconductor material on a substrate;
forming a transition metal layer by depositing a transition metal on the semiconductor layer; and
forming an electrode layer including a metallic transition metal dichalcogenide (TMD) material by supplying a chalcogen element to the transition metal layer and chalcogenizing the transition metal layer.

13. The method of claim 12, wherein the transition metal includes Mo, Nb, Pd, Pt, Ta, Ti, V, or W.

14. The method of claim 12, wherein the chalcogen element includes S, Se, or Te.

15. The method of claim 12, wherein the metallic TMD material includes VS₂, VSe₂, VTe₂, MoTe₂, NbS₂, NbSe₂, NbTe₂, WTe₂, TaS₂, TaSe₂, TaTe₂, TiS₂, TiSe₂, TiTe₂, PdS₂, PdSe₂, PtS₂, PtSe₂, or PtTe₂.

16. The method of claim 12, further comprising:
before the forming the electrode layer, forming an anti-oxidation layer on the transition metal layer.

17. The method of claim 16, wherein the anti-oxidation layer includes Au, TiN, TaN, Ru, HfO₂, Al₂O₃, ZrO₂, or SiO₂.

18. The method of claim 12, wherein the semiconductor layer includes a two-dimensional material.

19. The method of claim 18, wherein the semiconductor layer includes a TMD material.

20. The method of claim 12, wherein the semiconductor layer includes silicon.
